(19) United States
(12) Patent Application Publication
(10) Pub. No.: US 2009/0231040 A1
(43) Pub. Date: Sep. 17, 2009

(54) OUTPUT DRIVER HAVING PRE-EMPHASIS CAPABILITY

(75) Inventor: Young-soo Sohn, Gunpo-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: Samsung Electronics Co., Ltd., Suwon-si (KR)

(21) Appl. No.: 12/434,719

(22) Filed: May 4, 2009

Related U.S. Application Data
(62) Division of application No. 11/783,483, filed on Apr. 10, 2007.

(30) Foreign Application Priority Data
Apr. 28, 2006 (KR) 10-2006-0038867

(51) Int. Cl. H03F 3/45

(52) U.S. Cl. 330/253

(57) ABSTRACT

An output driver and an I/O apparatus including the output driver are disclosed. The output driver includes a driving unit having a first type transistor and a second type transistor connected in series, the driving unit amplifying an input signal applied to the gates of the first type transistor and the second type transistor and outputting the amplified signal to a node between the series connected first type transistor and second type transistor, a first source peaking unit connected between the first type transistor and a first voltage source and having a first impedance that varies in accordance with the frequency of the input signal, and a second source peaking unit connected between the second type transistor and a second voltage source and having a second impedance that varies in accordance with the frequency of the input signal.

### CROSS-REFERENCE TO RELATED APPLICATION

This is a divisional of application Ser. No. 11/783,483 filed on Apr. 10, 2007, which is incorporated herein by reference in its entirety.

### BACKGROUND OF THE INVENTION

1. Field of the Invention

The present invention relates to a semiconductor device. More particularly, the invention relates to an output driver having a pre-emphasis capability for use in a semiconductor device.

This application claims the benefit of Korean Patent Application No. 10-2006-0038867 filed on Apr. 28, 2006, the subject matter of which is hereby incorporated by reference.

2. Description of the Related Art

Various advancements in related design and fabrication technologies have led to dramatic improvements in the operating frequency of contemporary semiconductor devices. However, as the data communication frequencies between semiconductor devices have increased, problems associated with inter-symbol interference (ISI) have also increased.

In order to reduce ISI, some emerging semiconductor devices include an output driver having a pre-emphasis capability. This capability amplifies and outputs the high-frequency components of an output signal provided by the output driver.

Figures (FIGS.) 1A and 1B are block diagrams illustrating two approaches to the conventional implementation of pre-emphasis in an output driver. Specifically, in the method of FIG. 1A, a current signal and a past signal (i.e., a signal generated during a previous time period) are combined in an adder circuit 113 to generate an output. The past signal may be derived using a delay circuit 111 (e.g., a flip-flop or latch). Using the approach illustrated in FIG. 1A, the signal swing width is increased whenever the signal changes over time, and the high-frequency components of the signal are emphasized accordingly.

In the method of FIG. 1B, a current signal and a differentiated version of the current signal are combined in an adder circuit 133 to generate an output. The differentiated version of the current signal may be derived using a conventional differentiation circuit 131. Using the approach illustrated in FIG. 1B, it is possible to improve the quality of the high-frequency components of the current signal by detecting and increasing the corresponding signal edges.

The foregoing hardware approaches to signal pre-emphasis work well in the context of single phase signals (e.g., single clock edge derived signals). Unfortunately, many conventional output drivers must accommodate multi-phase signals. When multi-phase signals are used, it is not so easy to implement in hardware a method for delaying a signal or detecting signal edges.

For example, where multi-phase signals are communicated by semiconductor devices, a very high speed output signal may be generated. Unfortunately, the effective operating speed of the semiconductor device may actually exceed the operating capabilities of flip-flops used as a delay circuit. In such circumstances, multiple signals, each having a different delay time, may be applied to a plurality of multiplexers, and respective outputs of the multiplexers may then be applied to a plurality of output drivers. However, this approach increases the hardware load on the corresponding output drivers having pre-emphasis capability.

Accordingly, there is a need to develop an output driver capable of performing a pre-emphasis operation without increasing the hardware load.

### SUMMARY OF THE INVENTION

Embodiments of the present invention provide an output driver capable of performing a pre-emphasis operation using a source peaking method.

In one embodiment, the invention provides an output driver comprising; a driving unit having a first type transistor and a second type transistor connected in series, the driving unit amplifying an input signal applied to the gates of the first type transistor and the second type transistor and outputting the amplified signal to a node between the series connected first type transistor and second type transistor, a first source peaking unit connected between the first type transistor and a first voltage source and having a first impedance that varies in accordance with the frequency of the input signal, and a second source peaking unit connected between the second type transistor and a second voltage source and having a second impedance that varies in accordance with the frequency of the input signal.

In another embodiment, the invention provides an output driver circuit comprising; a plurality of source peaking drivers connected in parallel, each one of the plurality of source peaking drivers amplifying an input signal in accordance with a gain that varies with the frequency of the input signal and outputting an amplified signal.

In another embodiment, the invention provides an input/output driver apparatus, comprising; a source peaking driver circuit including a plurality of source peaking drivers connected in parallel, each amplifying an input signal in accordance with a gain controlled in relation to the frequency of the input signal and outputting an amplified signal, and an amplifying driver circuit including a plurality of amplifying drivers connected in parallel, each amplifying the input signal and outputting the amplified signal, wherein the plurality of source peaking drivers and the plurality of amplifying drivers are connected in parallel.

In another embodiment, the invention provides an output driver apparatus comprising; a source peaking amplifying circuit including a plurality of source peaking amplifiers connected in series, each amplifying differential input signals according to a gain controlled according to the frequency of the differential input signals and outputting corresponding amplified signals, and a differential amplifying circuit including a plurality of differential amplifiers connected in series, wherein the source peaking amplifying circuit and the differential amplifying circuit are connected in series.

### BRIEF DESCRIPTION OF THE DRAWINGS

FIG. 1A is a block diagram illustrating a pre-emphasis method performed in a conventional output driver;

FIG. 1B is a block diagram illustrating another pre-emphasis method performed in a conventional output driver;

FIG. 2 is a block diagram of a semiconductor device including a plurality of output drivers according to an embodiment of the present invention;

FIG. 3 is a circuit diagram illustrating a source peaking operation;

FIG. 4 is a circuit diagram of an output driver according to an embodiment of the present invention;

FIG. 5A is a circuit diagram of an amplifying driver included in an amplifying driver unit of FIG. 4, according to an embodiment of the present invention;

FIG. 5B is a circuit diagram of a source peaking driver included in a source peaking driver unit of FIG. 4, according to an embodiment of the present invention; and

FIGS. 6A through 6C are waveform diagrams illustrating performance of an output driver according to an embodiment of the present invention in comparison with a conventional output driver.

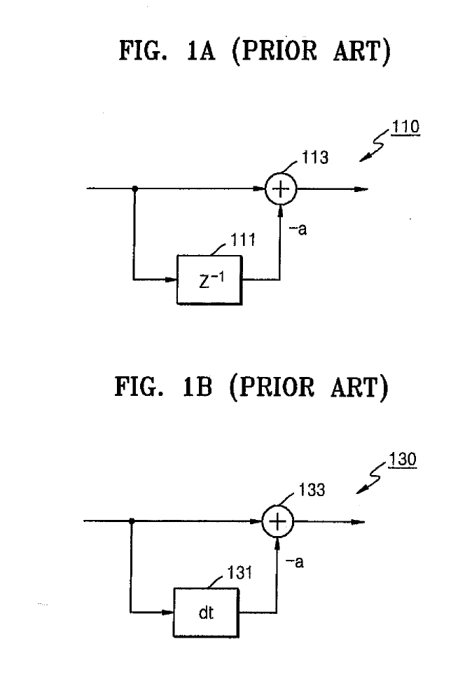

### DESCRIPTION OF EMBODIMENTS

Hereinafter, exemplary embodiments of the present invention will be described with reference to the accompanying drawings. Throughout the written description and drawings, like reference numerals denote like or similar elements.

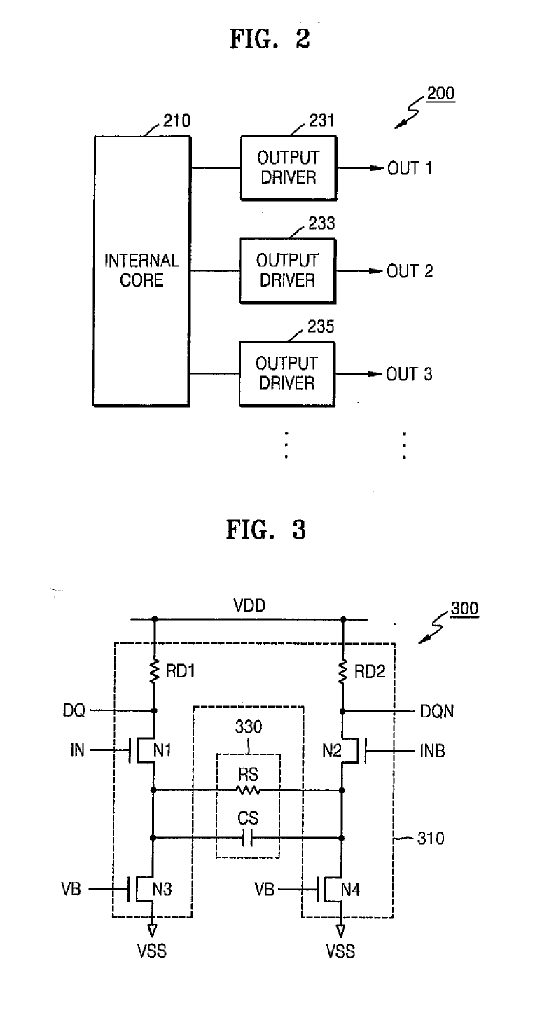

FIG. 2 is a block diagram of a semiconductor device 200 comprising a plurality of output drivers 231 through 235 according to an embodiment of the present invention. Semiconductor device 200 includes an internal core 210 and output drivers 231 through 235. In general, internal core 210 includes circuits necessary to the operation of semiconductor device 200.

Signals output from the circuits forming internal core 210 are output from semiconductor device 200 via the output drivers 231 through 235.

FIG. 3 is one example of a circuit diagram adapted to implement a source peaking method within the context of the present invention. The circuit illustrated in FIG. 3 may be viewed as a differential amplifier 300 implementing the source peaking method. In general, the source peaking method is used to increase the operating bandwidth of a differential amplifier. The operation of a differential amplifier using the source peaking method will now be described.

Differential amplifier 300 comprises a differential amplifying unit 310 and a source peaking unit 330.

Source peaking unit 330 includes a source peaking resistor RS and a source peaking capacitor CS connected in parallel between source terminals of a first transistor N1 and a second transistor N2.

The construction of differential amplifying unit 310 may be similar to that of a conventional differential amplifier. In the illustrated example, differential amplifying unit 310 includes first and second amplifying resistors RD1 and RD2 and first through fourth transistors N1 through N4.

The first and second amplifying resistors RD1 and RD2 are connected to a first voltage source VDD. The first transistor N1 is connected to the first amplifying resistor RD1, and a differential input signal IN is applied to the gate of the first transistor N1. The second transistor N2 is connected to the second amplifying resistor RD2 and complementary differential input signal INB is applied to the gate of the second transistor N2.

The third transistor N3 is connected between the first transistor N1 and a second voltage source VSS, and operates in response to an enable voltage VB applied to the gate of the third transistor N3. The fourth transistor N4 is connected between the second transistor N2 and the second voltage source VSS, and operates in response to the enable voltage VB applied to the gate of the fourth transistor N4.

As illustrated in FIG. 3, the first through fourth transistors N1 through N4 may be NMOS transistors and the first and second voltage sources VDD and VSS may be used. However, it will be apparent to one of ordinary skill in the art that the differential amplifier 300 may be embodied with other types of transistors and voltage sources.

Source peaking unit 330 is connected between a first node connecting the source of the first transistor N1 to the drain of the third transistor N3 and a second node connecting the source of the second transistor N2 to the drain of the fourth transistor N4.

When the differential input signals IN and INB applied to the gates of the first and second transistors N1 and N2 are high-frequency signals, the impedance apparent between the sources of the first and second transistors N1 and N2 is reduced, and the differential amplifier 300 operates similar to a general differential amplifier. In this case, the swing widths of output signals DQ and DQN are the same as those provided by the general differential amplifier.

However, when the differential input signals IN and INB applied to the gates (i.e., the differential input terminals) of the first and second transistors N1 and N2 are low-frequency signals, the impedance apparent between the sources of the first and second transistors N1 and N2 is increased. In this case, the swing widths of the output signals DQ and DQN are smaller than those provided by the general differential amplifier.

Thus, the gain of differential amplifier 300 varies in accordance with the frequency of the applied differential input signals IN and INB. That is, if the differential input signals have a relatively high frequency, differential amplifier 300 will have a comparatively large gain, but if the differential input signals have a relatively low frequency, differential amplifier 300 will have a comparatively small gain. Accordingly, a bandwidth for differential amplifier 300 may be larger than that provided by a similar general differential amplifier.

As described above, an output driver according to the present invention uses the above source peaking method. That is, according to an embodiment of the present invention, the high-frequency component of an input signal may be pre-emphasized by increasing the gain.

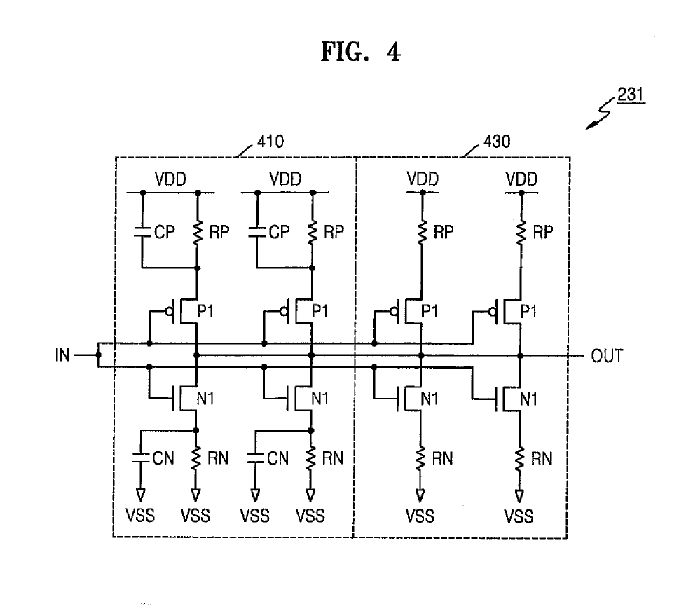

FIG. 4 is one possible circuit diagram of output driver 231 implemented in accordance with an embodiment of the invention. Output driver 231 of FIG. 4 may be used for each output driver 231 through 235 in the semiconductor device shown in FIG. 2. Output driver 231 amplifies an input signal IN and outputs an output signal OUT which is an amplified version of the input signal IN. The amplified output signal OUT may be provided to an external device via a conventional signal pad (not shown). In general, semiconductor devices are externally connected via a channel implemented, for example, in the form of a micro-strip line. Thus, the output signal OUT provided by output driver 231 may be provided via the channel connected to the semiconductor device via the pad.

Output driver 231 includes a source peaking driver unit 410 that operates with pre-emphasis provided by the source peaking method, and an amplifying driver unit 430 that operates without pre-emphasis. When the source peaking method is used, the amplified gain varies in accordance with the frequency of the input signal IN. Thus, source peaking driver unit 410 amplifies the input signal IN and outputs the amplified output signal OUT according to gain characteristics controlled by the frequency of the input signal IN.

It will be apparent to one of ordinary skill in the art that output driver 231 may be embodied with only source peaking driver unit 410. Additionally, output driver 231 may be used not only to amplify and output a signal generated by the circuits forming internal core 210 of the semiconductor device, but also to receive a signal transmitted to the semiconductor device via the channel (i.e., as an input driver as well).

Thus, when output driver 231 is used to receive a signal transmitted to the semiconductor device, source peaking driver unit 410 is disabled, and amplifying driver unit 430 operates as an on-die termination circuit.

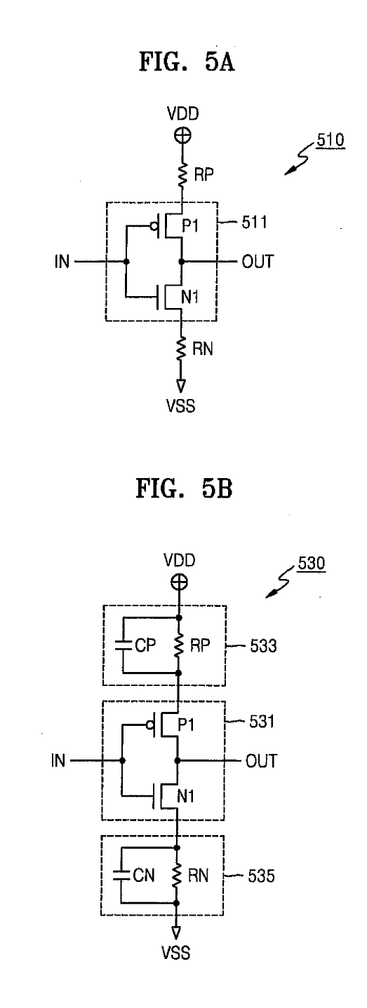

As illustrated in FIG. 4, source peaking driver unit 410 may include a plurality of source peaking drivers (two source peaking drivers are shown in FIG. 4), and amplifying driver unit 430 may include a plurality of amplifying drivers (two amplifying drivers are shown in FIG. 4). The source peaking drivers and the amplifying drivers are connected in parallel in the illustrated example. The operation of the source peaking drivers and the amplifying drivers will later be described with reference to FIGS. 5A and 5B.

The driving capability of output driver 231 is determined by the total number of the source peaking drivers and the amplifying drivers connected in parallel. Since the driving capability varies in accordance with channel bandwidth, the total number of the source peaking drivers and the amplifying drivers may be determined in relation to a desired channel bandwidth.

FIG. 5A is one possible circuit diagram of an amplifying driver 510 included in amplifying driver unit 430 of FIG. 4. FIG. 5B is one possible circuit diagram of a source peaking driver 530 included in source peaking driver unit 410 of FIG. 4.

Compared to amplifying driver 510, source peaking driver 530 further includes a source peaking capacitor CP for source peaking. Specifically, amplifying driver 510 includes a driving unit 511, a first amplifying resistor RP, and a second amplifying resistor RN. However, source peaking driver 530 further includes first and second source peaking capacitors CP and CN. The construction and operation of amplifying driver 510 according to an embodiment of the invention will first be described, and then source peaking driver 530 according to an embodiment of the invention will be described.

Driving unit 511 includes a first type transistor P1 and a second type transistor N1 that are connected in series. Driving unit 511 amplifies an input signal applied to the gates of the first type transistor P1 and the second type transistor N1 and outputs an amplified output signal OUT via a node connected to the first type transistor P1 and the second type transistor N1.

The first amplifying resistor RP is connected between the first type transistor P1 and a first voltage source VDD. The second amplifying resistor RN is connected between the second type transistor N1 and a second voltage source VSS.

In the illustrated example, it is assumed that the first type transistor P1 is a PMOS transistor, the second type transistor N1 is an NMOS transistor, the first voltage source VDD is a supply voltage source, and the second voltage source VSS is a ground voltage source. However, it will be apparent to those of ordinary skill in the art that the invention is not limited to only this configuration of transistor and signal types.

Referring to FIG. 5B, source peaking driver 530 includes a driving unit 531, a first source peaking unit 533, and a second source peaking unit 535. Driving unit 531 includes an NMOS transistor N1 and a PMOS transistor P1 connected in series. Driving unit 531 amplifies an input signal IN applied to the gates of the NMOS transistor N1 and the PMOS transistor P1, and outputs an amplified output signal OUT via a node to which the NMOS transistor N1 and the PMOS transistor P1 are connected.

First source peaking unit 533 includes a first source peaking resistor RP and a first source peaking capacitor CP, and second source peaking unit 535 includes a second source peaking resistor RN and a second source peaking capacitor CN. The first source peaking resistor RP and the first source peaking capacitor CP are connected in parallel, and the second source peaking resistor RN and the second source peaking capacitor CN are also connected in parallel.

First source peaking unit 533 is connected between the PMOS transistor P1 and the supply voltage source VDD, and second source peaking unit 535 is connected between the NMOS transistor N1 and the ground voltage source VSS.

As described above with respect to the source peaking method, the impedance between first and second source peaking units 533 and 535 is controlled in accordance with the frequency of the input signal IN. That is, the higher the frequency of the input signal IN, the smaller the impedances between the resistors RP and RN and between the capacitors CP and CN of first and second source peaking units 533 and 535, which are respectively connected to each other in parallel.

In contrast, the lower the frequency of the input signal IN, the greater the impedances between the resistors RP and RN and between the capacitors CP and CN of first and second source peaking units 533 and 535.

When the impedances of first and second source peaking units 533 and 535 change in accordance with the frequency of the input signal IN, the gain of output driver 530 also changes. That is, the gain of output driver 530 is controlled according to the frequency of the input signal IN.

In detail, the higher the frequency of the input signal IN, the less the impedances of first and second source peaking units 533 and 535, the greater the driving capability of driving unit 531, and the greater the gain of output driver 530.

In contrast, the lower the frequency of the input signal IN, the greater the impedances of first and second source peaking units 533 and 535, the less the driving capability of driving unit 531, and the less the gain of the output driver 530.

According to an embodiment of the invention, the resistance of the first source peaking resistor RP is preferably equal to that of the second source peaking resistor RN, and the capacitance of the first source peaking capacitor CP is preferably equal to that of the second source peaking capacitor CN. However, the present invention is not limited to only these relative values.

In the foregoing, an embodiment of the invention has been described with respect to a case which assumes that a plurality of source peaking drivers are used to implement an output driver. However, the output driver may be implemented using only a single source peaking driver.

As described above, since the gain of the source peaking driver may be controlled according to the frequency of an input signal, the use of the source peaking driver allows greater gain to be applied to an input signal containing high-frequency components, as compared with an input signal containing low-frequency components. Accordingly, pre-emphasis may be obtained via the variable gain characteristics of the source peaking driver.

The foregoing output driver circuit has been described as including a plurality of source peaking drivers and a plurality of conventional amplifying drivers. However, an output driver may be alternately realized using differential amplifier 300 of FIG. 3 (hereinafter referred to as the “source peaking amplifier 300”). Hereinafter, an output driver that includes source peaking amplifier 300 and a general differential amplifier, according to another embodiment of the present invention, will be described.

From the operation of source peaking amplifier 300 which has been described with reference to FIG. 3, it is noted that even source peaking amplifier 300 of the output driver has a larger gain for a high-frequency component of an input signal than for a low-frequency component of the input signal. Thus, it is possible to pre-emphasize the high-frequency components of an input signal even when the input signal is amplified by using source peaking amplifier 300.

An output driver according to another embodiment of the invention includes a source peaking amplifying circuit and a differential amplifying circuit. The source peaking amplifying circuit includes one or more source peaking amplifiers, such as the source peaking amplifier 300 illustrated in FIG. 3. The differential amplifying circuit may include one or more general differential amplifier(s).

In this case, the source peaking amplifiers included in the source peaking amplifying circuit are connected in series. That is, in the source peaking amplifiers connected in series, a differential output terminal of each preceding source peaking amplifier is connected to a differential output terminal of the following source peaking amplifier.

Also, a signal output from an internal core of a semiconductor device and an inversion signal of the output signal are input to a differential input terminal of a first-stage differential input terminal of the source peaking amplifiers connected in series.

The differential amplifiers included in the differential amplifying circuit are also connected in series, and the source peaking amplifying circuit and the differential amplifying circuit are also connected in series. That is, the first source peaking amplifier of the source peaking amplifiers connected in series in the source peaking amplifying circuit, is connected in series to the first differential amplifier of the differential amplifiers connected in series in the differential amplifying circuit.

As described above with reference to FIG. 3, source peaking amplifier 300 includes differential amplifying unit 310 and source peaking unit 330, and differential amplifying unit 310 amplifies the differential input signals IN and INB applied to the differential input terminals of the first and second transistors N1 and N2 according to a defined gain characteristic, and outputs the differential output signals DQ and DQN.

Source peaking unit 330 is connected to differential amplifying unit 310, and the impedance of source peaking unit 330 is controlled in accordance with the frequency of the differential input signals. The gain of differential amplifying unit 310 is determined according to the impedance thereof according to the frequency of the differential input signals.

Similarly to output driver 231 of FIG. 4, the total number of the source peaking amplifiers included in the source peaking amplifying circuit and the total number of the differential amplifiers included in the differential amplifying circuit may be determined according to a desired bandwidth for the channel connected to the output driver.

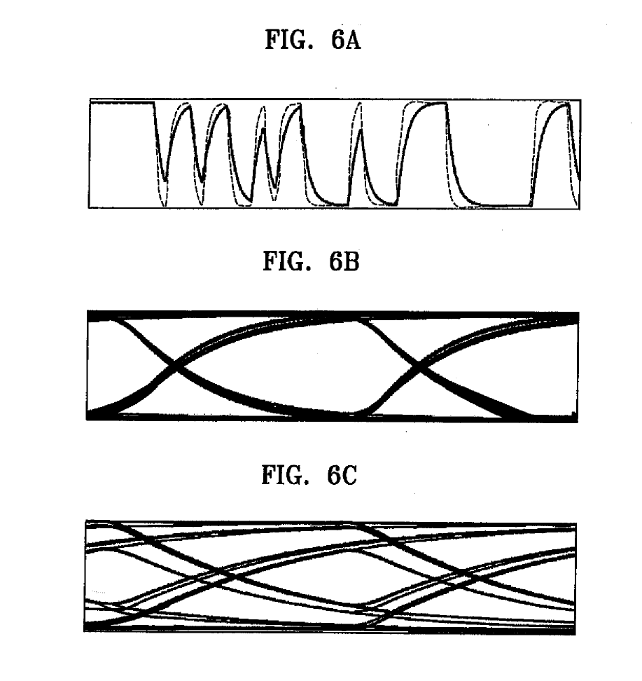

FIGS. 6A through 6C are waveform diagrams illustrating the performances of an exemplary output driver implemented in accordance with an embodiment of the present invention, as compared with a conventional output driver. Specifically, FIG. 6A shows a waveform for a signal output from an output amplifier. In FIG. 6A, the dotted line denotes a waveform of a signal output from the output amplifier when the output driver according to an embodiment of the present invention is used, and the solid line denotes a waveform of a signal output from the output amplifier when the conventional output driver is used.

As may be seen from the waveforms compared in FIG. 6A, when an output driver according to an embodiment of the present invention is used, the high-frequency component(s) of the output signal are enhanced through pre-emphasis.

FIG. 6B is an eye diagram for a signal output from an output amplifier including an output driver according to an embodiment of the present invention, and FIG. 6C is an eye diagram for a signal output from an output amplifier including a conventional output driver.

As may be seen from FIGS. 6B and 6C, the eye apparent in the eye diagram of FIG. 6B is much larger and better formed than the eye of the eye diagram of FIG. 6C.

As described above, an output driver according to an embodiment of the invention performs pre-emphasis using the source peaking method, thereby reducing hardware load on a constituent semiconductor device.

While this invention has been particularly shown and described with reference to preferred embodiments thereof, it will be understood by those skilled in the art that various changes in form and details may be made therein without departing from the scope of the invention as defined by the appended claims.

1-4. (canceled)

5. A source peaking amplifier comprising:
a differential amplifying unit amplifying differential input signals applied to differential input terminals according to a gain and outputting corresponding amplified signals as differential output signals; and
a source peaking unit connected to the differential amplifying unit and having an impedance is controlled in accordance with frequencies of the differential input signals,
wherein the gain is determined by the impedance of the source peaking unit.

6. The source peaking amplifier of claim 5, wherein the differential amplifying unit comprises:
a first amplifying resistor connected to a first voltage source;
a second amplifying resistor connected to the first voltage source;
a first transistor connected to the first amplifying resistor, wherein one of the differential input signals is applied to the gate of the first transistor;
a second transistor connected to the second amplifying resistor, wherein the other differential input signal is applied to the gate of the second transistor;
a third transistor connected between the first transistor and a second voltage source, the third transistor operating in response to an enable voltage applied to the gate of the third transistor; and
a fourth transistor connected between the second transistor and the second voltage source, the fourth transistor operating in response to the enable voltage applied to the gate of the fourth transistor.

7. The source peaking amplifier of claim 5, wherein the source peaking unit is connected between a node connecting the first transistor and the third transistor and a node connecting the second transistor and the fourth transistor, wherein the source peaking unit comprises a source peaking resistor and a source peaking capacitor connected in parallel.

8. The source peaking amplifier of claim 6, wherein the first transistor, the second transistor, the third transistor and the fourth transistor are NMOS.

9. The source peaking amplifier of claim 8, wherein the first voltage source is a supply voltage, and the second voltage source is ground.

10. The source peaking amplifier of claim 5, wherein gain for the source peaking amplifier is controlled in accordance with the frequencies of the differential input signals.

11. The source peaking amplifier of claim 10, wherein the gain of the source peaking amplifier decreases as the frequencies of the differential input signals decrease, and the gain of the source peaking amplifier increases as the frequencies of the differential input signals increase.

12. An output driver apparatus comprising:
a source peaking amplifying circuit including a plurality of source peaking amplifiers connected in series, each amplifying differential input signals according to a gain controlled according to the frequency of the differential input signals and outputting corresponding amplified signals; and
a differential amplifying circuit including a plurality of differential amplifiers connected in series,
wherein the source peaking amplifying circuit and the differential amplifying circuit are connected in series.

13. The output driver apparatus of claim 12, wherein each source peaking amplifier comprises:
a differential amplifying unit amplifying the different input signals applied to differential input terminals according to the gain and outputting the corresponding amplified signals as differential output signals; and
a source peaking unit connected to the differential amplifying unit and having an impedance is controlled in accordance with the frequencies of the differential input signals,
wherein the gain is determined by the impedance of the source peaking unit.

14. The output driver apparatus of claim 13, wherein the differential amplifying unit comprises:
a first amplifying resistor connected to a first voltage source;
a second amplifying resistor connected to the first voltage source;
a first transistor connected to the first amplifying resistor, wherein one of the differential input signals is applied to the gate of the first transistor;
a second transistor connected to the second amplifying resistor, wherein the other differential input signal is applied to the gate of the second transistor;
a third transistor connected between the first transistor and a second voltage source, the third transistor operating in response to an enable voltage applied to the gate of the third transistor; and
a fourth transistor connected between the second transistor and the second voltage source, the fourth transistor operating in response to the enable voltage applied to the gate of the fourth transistor.

15. The output driver apparatus of claim 13, wherein the source peaking unit is connected between a node connecting the first transistor and the third transistor and a node connecting the second transistor and the fourth transistor, wherein the source peaking unit comprises a source peaking resistor and a source peaking capacitor connected in parallel.

16. The output driver apparatus of claim 14, wherein the first transistor, the second transistor, the third transistor and the fourth transistor are NMOS.

17. The output driver apparatus of claim 14, wherein the first voltage source is a supply voltage and the second voltage source is ground.

18. The output driver apparatus of claim 12, wherein the gain of the source peaking amplifiers decreases as the frequencies of the differential input signals decrease, and the gain of the source peaking amplifier increases as the frequencies of the differential input signals increase.

19. The output driver apparatus of claim 12, wherein a total number of the source peaking amplifiers included in the source peaking amplifying circuit and a total number of the differential amplifiers included in the differential amplifying circuit are determined in accordance with a desired bandwidth for a channel connected to the output driver apparatus.

20. An output driver apparatus comprising:
a source peaking amplifying circuit including a plurality of source peaking amplifiers connected in series, each amplifying differential input signals according to a gain controlled according to the frequency of the differential input signals and outputting I corresponding amplified signals; and
a differential amplifying circuit including a plurality of differential amplifiers connected in series,
wherein the source peaking amplifying circuit and the differential amplifying circuit are connected in series,
and wherein the source peaking amplifying circuit is disabled when an external signal is received.

21. The output driver apparatus of claim 20, wherein the differential amplifying circuit operates as an on-die termination circuit.
